(19) United States
(12) Patent Application Publication
(10) Pub. No.: US 2014/0159636 A1
(43) Pub. Date: Jun. 12, 2014

(54) SOLAR ENERGY HARVESTING SKYLIGHTS AND WINDOWS WITH INTEGRATED ILLUMINATION

(71) Applicant: QUALCOMM MEMS TECHNOLOGIES, INC., San Diego, CA (US)

(72) Inventors: Fan Yang, Sunnyvale, CA (US); Russell W. Gruhlke, Milpitas, CA (US); Ying Zhou, Milpitas, CA (US)

(73) Assignee: QUALCOMM MEMS Technologies, Inc., San Diego, CA (US)

(21) Appl. No.: 13/708,828

(22) Filed: Dec. 7, 2012

(51) Int. Cl. H02J 7/00; H02J 4/00; H01L 31/0232; H01L 31/18; H05K 13/00

(52) U.S. Cl. CPC H02J 7/0052; H01L 31/18; H05K 13/0023; H01L 31/02327; H02J 4/00
USPC 320/101; 29/592.1; 29/825; 250/578.1; 307/43

(57) ABSTRACT

This disclosure provides systems, methods and apparatus that can generate PV power and simultaneously provide artificial lighting. The devices disclosed herein include a first optical structure having a plurality of focusing elements that can collect and focus ambient light onto a first set of light redirecting elements that is optically coupled to at least photovoltaic (PV) cell. The devices also include at least one illumination source that is optically coupled to a first edge of a second optical structure including a second set of light redirecting elements that can direct light from the at least one illumination source out of the device to provide artificial lighting. The at least one photovoltaic cell is coupled to a second edge of the second optical structure.

### TECHNICAL FIELD

This disclosure relates to the field of light collectors and concentrators, and more particularly to devices that combine photovoltaic power generation and artificial lighting.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy and in converting light energy to heat or electricity, and the variation in the solar energy collection depending on the time of the day and the month of the year.

A photovoltaic (PV) cell can be used to convert solar energy to electrical energy, and such systems using PV cells may have conversion efficiencies between about 10-20%. PV cells can be made very thin and are not big and bulky as other devices that use solar energy. For example, PV cells can range in width and length from a few millimeters to 10's of centimeters. Although, the electrical output from an individual PV cell may range from a few milliwatts to a few watts, due to their compact size, multiple PV cells may be connected electrically and packaged to produce, in total, a significant amount of electricity. For example, multiple solar panels each including a plurality of PV cells can be used to produce sufficient electricity to satisfy the power needs of some homes.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight may be large. However, for many applications such as, for example, providing electricity to residential and commercial properties, charging automobile batteries and other navigation instruments, it is desirable that the light collectors and/or concentrators are compact in size.

PV materials are also increasingly replacing conventional building materials in parts of the building envelope such as windows, roofs, skylight or facades. PV materials incorporated in building envelopes can function as principal or secondary sources of electrical power and help in achieving zero-energy buildings. One of the currently available building-integrated photovoltaic (BIPV) products is a crystalline Si BIPV, which is made of an array of opaque crystalline Si cells sandwiched between two glass panels. Another available BIPV product is a thin film BIPV which is manufactured by blanket depositing PV film on a substrate and laser scribing of the deposited PV film from certain areas to leave some empty spaces and improve transmission. However, both available BIPV products described above may suffer from low transmission (5-20%) disruptive appearance. Additionally, the thin film BIPV may also be expensive to reasonably manufacture.

### SUMMARY

The systems, methods and devices of the disclosure each have several innovative aspects, no single one of which is solely responsible for the desirable attributes disclosed herein.

One innovative aspect of the subject matter described in this disclosure can be implemented in a device comprising a first optical structure having a plurality of lenses, and a second optical structure disposed below the first optical structure. Each lens is configured to focus light incident on the lens toward a focal point disposed below the plurality of lenses. The first optical structure has a forward surface and a rearward surface. In various embodiments, the plurality of lenses can include cylindrical-shaped collection lenses that are aligned in parallel and extending across the forward or the rearward surface of the first optical structure. In various embodiments, the forward surface of the first optical structure can include a first portion and a second portion. The plurality of lenses can be disposed over the first portion of the forward surface and not disposed over the second portion of the forward surface. In various embodiments, the plurality of lenses can be configured such that approximately 1% to approximately 30% of light that is incident on the first optical structure is re-directed to the at least one photovoltaic cell.

The second optical structure has a forward surface, a rearward surface, a first edge extending between the rearward surface and the forward surface of the second optical structure, and a second edge extending between the rearward surface and the forward surface of the second optical structure. The device further includes at least one light source disposed along the first edge of the second optical structure and a plurality of turning features that are disposed in the second optical structure. The plurality of turning features are configured to turn light received from the at least one light source out of the rearward surface of the second optical structure. In various embodiments, each light turning feature can include a prismatic feature extending in a direction orthogonal to the alignment of the cylindrical-shaped collection lenses. In various embodiments, the light turning features can be disposed below the second portion of the forward surface of the first optical structure.

The device further includes at least one photovoltaic cell that is disposed along the second edge of the second optical structure. The device further includes a plurality of light redirection features. Each of the plurality of light redirection features is disposed in the second optical structure at a focal point of one of the plurality of lenses. The plurality of light redirection features are configured to redirect at least a portion of light focused by the plurality of lenses toward the at least one photovoltaic cell. In various embodiments, at least one of the light turning features can be disposed between at least two of the light redirection features.

In various embodiments, the second optical structure can be offset from the first optical structure by a separating layer having a refractive index lower than a refractive index of the second optical structure. The separating layer of material can include air, nitrogen, or argon. The device can further comprise a battery that is electrically coupled to the at least one photovoltaic cell. In various embodiments, the at least one light source can be electrically coupled to the battery. In various embodiments, the at least one photovoltaic cell can be electrically coupled to an electrical grid.

Another innovative aspect of the subject matter described in this disclosure can be implemented in a device including means for focusing at least a portion of light incident on the device toward a plurality of focal points disposed below the light focusing means. The device further comprises a means for guiding light, the light guiding means disposed below the light focusing means and having at least a first edge and a second edge. The device further comprises at least one photovoltaic cell disposed along the first edge of the light guiding means, means for redirecting light from the plurality of focal points toward the at least one photovoltaic cell, and means for providing artificial light from the light guiding means in a direction away from the light focusing means.

The device is configured such that at least a portion of light incident on the device can pass through the light focusing means, light redirecting means, and artificial light providing means without being redirected toward the at least one photovoltaic cell. In various embodiments, the light focusing means can include a plurality of lenses. In various embodiments, the light redirecting means can include a plurality of light redirection features disposed in the light guiding means. Each light redirection feature can be configured to redirect light incident thereon toward the at least one photovoltaic cell. Each light redirection feature can be aligned with a focal point of one of the plurality of lenses. In various embodiments, the artificial light providing means can include a plurality of light turning features that are disposed in the light guiding means, and at least one light source disposed along the second edge of the light guiding means. Each light turning feature can be configured to turn light received from the at least one light source in a direction away from the light guiding means.

Another innovative aspect of the subject matter described in this disclosure includes a method of manufacturing a device. The method includes providing a first optical structure having a plurality of lenses, and disposing a second optical structure below the first optical structure. The first optical structure has a forward surface and a rearward surface. The second optical structure has a forward surface, a rearward surface, a first edge extending between the rearward surface and the forward surface of the second optical structure, and a second edge extending between the rearward surface and the forward surface of the second optical structure. The method further includes disposing at least one light source disposed along the first edge of the second optical structure, and disposing at least one photovoltaic cell along the second edge of the second optical structure. The method further includes forming a plurality of turning features and forming a plurality of light redirection features. The plurality of turning features and the plurality of light redirection features are disposed in the second optical structure. Each of the plurality of lenses is configured to focus light incident on the lens toward a focal point disposed below the plurality of lenses. The plurality of turning features are configured to turn light received from the at least one light source out of the rearward surface of the second optical structure. The plurality of light redirection features are disposed at a focal point of one of the plurality of lenses and are configured to redirect at least a portion of light incident on the forward surface of the first optical structure toward the at least one photovoltaic cell.

In various embodiments, the plurality of lenses can include cylindrical-shaped collection lenses that are aligned in parallel and extend across the forward surface of the first optical structure. In various embodiments, each light turning feature can include a prismatic feature extending in a direction orthogonal to the alignment of the cylindrical-shaped collection lenses. At least some of the light turning features can be formed between at least two of the light redirection features. In various embodiments, the forward surface of the first optical structure can include a first portion and a second portion and the plurality of lenses can be disposed over the first portion of the forward surface and not over the second portion of the forward surface. In various embodiments, the light turning features can be formed below the second portion of the forward surface of the first optical structure.

The methods described herein, for example, the above-described methods, can further include providing a battery and electrically coupling the at least one photovoltaic cell to the battery. Various embodiments of the method can further include electrically coupling the at least one light source to the battery and/or electrically coupling the at least one photovoltaic cell to an electrical grid.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIG. 1A illustrates a perspective view of an implementation of a device including a first optical structure that is optically coupled to one or more PV cells and a second optical structure that is optically coupled to one or more sources of light, the first optical structure having a plurality of focusing elements and light redirecting elements and the second optical structure having a plurality of light redirecting elements.

FIG. 1B is a top view of the implementation depicted in FIG. 1A.

FIGS. 1C-1D illustrate a side view of the implementation depicted in FIG. 1A along the axis 1C shown in FIG. 1B.

FIG. 2A illustrates a perspective view of an implementation of a device that includes a light collector that is optically coupled to one or more sources of light and a light guide that is optically coupled to one or more PV cells, the light collector having a plurality of optical focusing elements and light redirecting elements and the light guide including a plurality of light redirecting elements.

FIG. 2B is a top view of the implementation depicted in FIG. 2A.

FIG. 2C illustrates a side view of the implementation that is depicted in FIG. 2A.

FIG. 2D also illustrates a side view of the implementation that is depicted in FIG. 2A.

FIG. 3A illustrates a perspective view of an implementation of a device including a light collector that is optically coupled to one or more sources of light and a light guide that is optically coupled to one or more PV cells, the light collector having a plurality of optical focusing elements and light redirecting elements and the light guide including a plurality of light redirecting elements.

FIG. 3B is a top view of the implementation depicted in FIG. 3A.

FIGS. 3C and 3D illustrates a side view of the implementation depicted in FIG. 3A.

FIG. 4A illustrates a top view of an implementation of a device that includes a light collector that is optically coupled to one or more sources of light and a light guide that is optically coupled to one or more PV cells, the light collector having a plurality of half-cylinder shaped focusing elements and light redirecting elements having a longitudinal axis that is orthogonal to the cylindrical axis of the half-cylinder shaped focusing elements, the light guide including a plurality of light redirecting elements.

FIG. 4B is a side view of the implementation depicted in FIG. 4A along an axis parallel to the x-axis.

FIG. 4C is a side view of the implementation depicted in FIG. 4A along an axis parallel to the y-axis.

FIG. 5A illustrates a top view of an implementation of a device that includes a light collector that is optically coupled to one or more sources of light and a light guide that is optically coupled to one or more PV cells, the light collector having a plurality of half-cylinder shaped focusing elements and light redirecting elements having a longitudinal axis that is orthogonal to the cylindrical axis of the half-cylinder shaped focusing elements, the light guide including a plurality of light redirecting elements.

FIG. 5B is a side view of the implementation depicted in FIG. 5A along an axis parallel to the x-axis.

FIG. 5C is a side view of the implementation depicted in FIG. 5A along an axis parallel to the y-axis.

FIG. 6A is a top view of an implementation of a device including a light collector having a plurality of focusing elements and a light guide that is optically coupled to one or more sources of light and one or more PV cells having light receiving surfaces disposed along a direction that is orthogonal to direction along which the light emitting surfaces of the one or more sources of light are disposed, the light guide including a first set of light redirecting elements and a second set of light redirecting elements.

FIG. 6B is a side view of the implementation depicted in FIG. 6A along an axis parallel to the x-axis.

FIG. 6C is a side view of the implementation depicted in FIG. 6A along an axis parallel to the y-axis.

FIG. 7A illustrates a perspective view of an implementation of a device including a light collector having two sets of focusing elements and a light guide that is optically coupled to one or more sources of light and one or more PV cells disposed along a direction that is orthogonal to the one or more sources of light, the light guide including a plurality of light redirecting elements.

FIG. 7B is a top view of the implementation depicted in FIG. 7A.

FIGS. 7C and 7D illustrate side views of the implementation depicted in FIG. 7A.

FIG. 8A illustrates a perspective view of an implementation of a device including a light collector having a plurality focusing elements and a light guide including a first of set of redirecting elements and a second set of light redirecting elements, the second set of light redirecting elements having a varying density.

FIG. 8B is a top view of the implementation depicted in FIG. 8A.

FIGS. 8C and 8D illustrate side views of the implementation depicted in FIG. 8A.

FIGS. 9A and 9B are flow charts illustrating two different examples of a method of manufacturing an implementation of a PV power generating luminaire.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured to receive radiation from a source and generate power using the radiation. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. Some of the implementations described herein can be used in BIPV products such as windows, roofs, skylights, doors or facades. Some of the implementations described herein can be used to charge vehicle or watercraft batteries, power navigational instruments, to pump water and for solar thermal generation. The implementations described herein can also find use in aerospace and satellite applications, and other solar power generation applications.

As discussed more fully below, in various implementations described herein, a device that combines photovoltaic energy generation and natural and/or artificial lighting. The device includes a light collector is optically coupled to a PV cell such that light incident on a portion of the device is provided to the PV cell to generate electrical power. The light collector can include a plurality of focusing elements that can receive light incident on an exposed surface of the light collector and direct the received light towards a light guide as a focused beam of light. The light guide can include a first set of redirecting elements that can redirect the focused beam of light towards one or more PV cells that are disposed along one or more edges of the light guide. In various implementations described herein, the device also includes one or more sources of illumination (such as, for example, light emitting diodes (LEDs)) and a second set of light redirecting elements including prismatic or trapezoidal optical features that are configured to redirect (e.g., refract, scatter, diffract, or diffuse) light out of the device, providing artificial light from the LEDs. In various implementations, the size, density (or fill factor) of the plurality of focusing elements and the first and second set of light redirecting elements can be selected such that a portion of the light incident on the light collector is transmitted out of the light collector to simultaneously provide natural and artificial lighting.

In some implementations described herein, the LEDs can be coupled to the edges of the light collector and the second set of light redirecting elements can be disposed on the light collector such that they are adjacent or rearward of the plurality of focusing elements. In some implementations, the LEDs can be coupled to the edges of the light guide and the second set of light redirecting elements can be disposed on the light guide such that they are adjacent, rearward or forward of the first set of light redirecting elements.

Particular implementations of the subject matter described in this disclosure can be implemented to realize one or more of the following potential advantages. A device can be used to collect, concentrate, and direct sunlight or ambient light to PV cells in devices that convert light energy into electricity with increased efficiency and lower cost. Additionally, the implementations described herein can be configured to provide artificial lighting by redirecting light out of the device, where the light is from LEDs included in the device. Furthermore, by selecting the density of the focusing elements, and the first and second set of redirecting elements, a portion of the incident sunlight or ambient light can also be transmitted through the device to provide natural lighting. Accordingly, the various implementations of the PV power generating device integrated with a luminaire as described herein can be used to provide power and natural/artificial lighting. The implementations described herein can be integrated in architectural structures such as, for example, windows, roof, skylights, or facades, to simultaneously generate PV power and provide artificial/natural lighting to the interior of the architectural structures. Some implementations of the light collector, described herein can efficiently collect light at various times during the day or the year. For example, the implementations of the light collector described herein can efficiently collect light incident at noon when sun is overhead and sunlight is incident at angles closer to a surface normal of the light collector as well as in the mornings and evening when light is incident at non-normal angles.

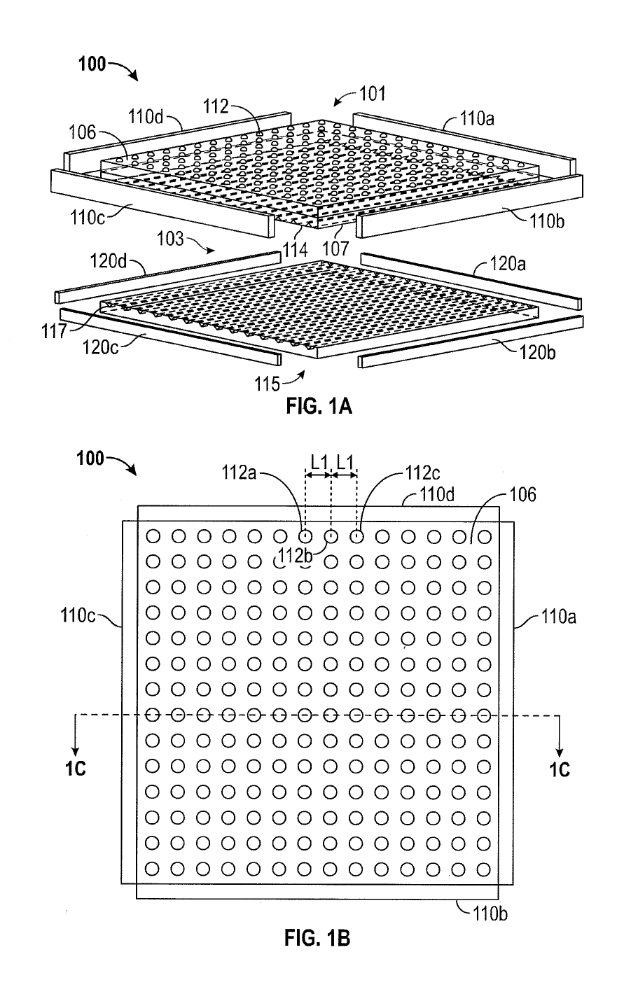

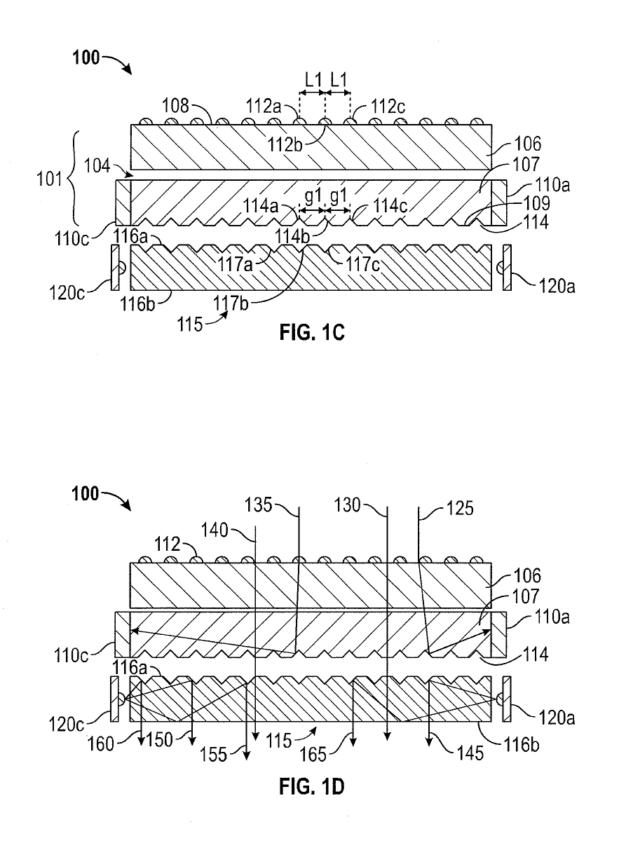

FIG. 1A illustrates a perspective view of an implementation of a device 100 including a first optical structure 101 that is optically coupled to one or more PV cells 110a, 110b, 110c and 110d. The device 100 also includes a second optical structure 115 that is optically coupled to one or more sources of light 120a, 120b, 120c and 120d. The first optical structure includes a plurality of focusing elements 112 and light redirecting elements 114 and the second optical structure includes a plurality of light redirecting elements 117. In the illustrated implementation, the first optical structure 101 is the PV power generating device and the second optical structure 115 is the luminaire. In various implementations, the thickness of the first optical structure 101 and the second optical structure 115 can be in the range from approximately 5 mm-30 mm. In various implementations, a gap 103 may be included between the first optical structure 101 and the second optical structure 115. The gap 103 can include a material having a lower refractive index than the material of the second optical structure 115. For example, in various implementations, the gap 103 can include air, nitrogen, argon or some other viscous material. In some implementations, the gap 103 can include a material that matches the refractive index of the first optical structure 101 to the refractive index of the second optical structure 115. In other implementations, the gap 103 can be wholly or partially devoid of material or substance, and can be a vacuum. The height of the gap 103 can vary between approximately 1 mm-50 mm. In some implementations, the material of the first optical structure 101 can have a lower refractive index than the material of the second optical structure 115 such that the gap 103 can be eliminated.

The first optical structure 101 may have a light collector 106 and a light guide 107. The light collector 106 includes the plurality of focusing elements 112 and the light guide 107 includes the plurality of light redirecting elements 114. In various implementations, the overall thickness of the device 100 can vary and be in the range from about 1 inch-8 inches.

The PV cells 110a-110d can convert light into electrical power. In various implementations, the PV cells 110a-110d can include solar cells. The PV cells 110a-110d can include a single or a multiple layer p-n junction and may be formed of silicon, amorphous silicon or other semiconductor materials such as Cadmium telluride. In some implementations, PV cells 110a-110d can include photo-electrochemical cells. Polymer or nanotechnology may be used to fabricate the PV cells 110a-110d. In various implementations, PV cells 110a-110d can include multi-spectrum layers, each multi-spectrum layer having a thickness between approximately 1 μm and approximately 250 μm. The multi-spectrum layers can further include nanocrystals dispersed in polymers. Several multi-spectrum layers can be stacked to increase efficiency of the PV cells 110a-110d.

FIG. 1B is a top view of the implementation 100 depicted in FIG. 1A. FIGS. 1C-1D illustrate the side view of the implementation 100 depicted in FIG. 1A along the axis 1C shown in FIG. 1B. As seen from the side views depicted in FIGS. 1C and 1D, the light collector 106 has a forward surface 108 and a rearward surface opposite the forward surface 108. The light guide 107 has a rearward surface 109 and a forward surface opposite the rearward surface 109. The forward surface of the light guide 107 faces the rearward surface of the light collector 106. A person having ordinary skill in the art will appreciate that the terms “forward” and “rearward” as used in referring to light collector/light guide surfaces herein do not indicate a particular absolute orientation, but instead are used to indicate a light collecting surface (“forward surface”) on which ambient light is incident and a surface where a portion of the incident light received on the forward surface can propagate out from (“rearward surface”). A plurality of edges is enclosed between the forward and rearward surfaces of the light collector 106 and the light guide 107. As illustrated in FIGS. 1A-1D, one or more PV cells 110a-110d is disposed with respect to the edges of the light collector 106 and/or the light guide 107. In various implementations, the light collector 106 and/or the light guide 107 may be optically coupled to the PV cells 110a-110d by using optical coupling elements such as lenses, fibers, collimators, prisms, etc.

In various implementations, the light collector 106 and/or the light guide 107 can include a transparent or transmissive material such as glass, plastic, polycarbonate, polyester or cyclo-olefin. The light collector 106 and/or the light guide 107 may be formed as a plate, sheet or film, and fabricated from a rigid or a semi-rigid material. In various implementations, portions of the light collector 106 and/or the light guide 107 may be formed from a flexible material. In some implementations, the forward surface 108 and the rearward surface of the light collector 106 can be parallel or nearly so. In other implementations, the light collector 106 can be wedge shaped such that the forward surface 108 and the rearward surface are inclined with respect to each other. In some implementations, the forward surface and the rearward surface 109 of the light guide 107 can be parallel or nearly so. In other implementations, the light guide 107 can be wedge shaped such that the forward surface and the rearward surface 109 are inclined with respect to each other.

In various implementations, the light collector 106 may be separated from the light guide 107 by a gap 104. The gap 104 can include a material having a lower refractive index than the material of the light guide 107. For example, in various implementations, the gap 104 can include air, nitrogen, argon or some other viscous material. In some implementations, the gap 104 can include a material that matches the refractive index of the light collector 106 to the refractive index of the light guide 107. In other implementations, the gap 104 can be wholly or partially devoid of material or substance, and can be a vacuum. The height of the gap 104 can vary between approximately 1 mm-50 mm. In some implementations, the material of light collector 106 can have a lower refractive index than the material of the light guide 107 such that the gap 104 can be eliminated.

In various implementations, the second optical structure 115 can include a transparent or transmissive material such as glass, plastic, polycarbonate, polyester or cyclo-olefin. The second optical structure 115 may be formed as a plate, sheet or film, and fabricated from a rigid or a semi-rigid material. In various implementations, portions of the second optical structure 115 may be formed from a flexible material. In various implementations, the second optical structure 115 can be configured as a light guide. The second optical structure 115 has a forward surface 116a and a rearward surface 116b. The forward surface 116a faces the first optical structure 101 and the rearward surface 116b is opposite the forward surface 116a. In some implementations, the forward surface 116a and the rearward surface 116b of the second optical structure 115 can be parallel or nearly so. In other implementations, the second optical structure 115 can be wedge shaped such that the forward surface 116a and the rearward surface 116b are inclined with respect to each other. A plurality of edges is included between the forward and rearward surfaces of the second optical structure 115 and the one or more sources of light 120a-120d are disposed with respect to the plurality of edges.

In various implementations, the one or more sources of light 120a-120d can be disposed to directly inject light into one or more edges of the second optical structure 115. In some implementations, the one or more sources of light 120a-120d may be optically coupled to one or more edges of the second optical structure 115 via optical elements such as, for example, lenses, prisms, collimators, optical fibers, etc. The optical elements can be configured to guide or inject light emitted by the one or more sources of light 120a-120d into one or more edges of the second optical structure 115. The one or more sources of light 120a-120d can include LEDs, edge emitters, cold cathode tube, fluorescent illuminators, etc.

In the illustrated implementation, the plurality of focusing elements 112 are disposed on, or over, the forward surface 108 of the light collector 106. However, in other implementations, the plurality of focusing elements 112 can be disposed on the rearward surface of the light collector 106. In some implementations, the plurality of focusing elements 112 can be formed on the forward or rearward surface of the light collector 106. In some implementations, a film, a layer or a plate provided with the plurality of focusing elements 112 can be adhered, attached or laminated to the forward or rearward surface of the light collector 106. In various other implementations, the plurality of focusing elements 112 can be disposed throughout the volume of the light collector 106. The plurality of focusing elements 112 can be formed by a variety of methods and processes, including lithography, etching, and embossing.

In various implementations, the plurality of focusing elements 112 can include a plurality of lenses, a lenslet array, an array of microlenses, or a combination thereof. The plurality of focusing elements 112 can have hemispherical, hemi-cylindrical, parabolic or elliptical surfaces. The curved surface of the plurality of focusing elements 112 can have a transversal size D (for example, diameter) that is between approximately 4 mm and approximately 20 mm. Each of the plurality of focusing elements 112 is characterized by a focal length F that can depend on the transversal size D and the curvature of the curved surface of the focusing element. In various implementations, the focal length F can be between approximately 3 mm and approximately 80 mm. In some implementations, each of the plurality of focusing elements 112 can have the same transversal size D and/or focal length F. In other implementations, the transversal size D and/or the focal length F for some of the plurality of focusing elements 112 can be different from the transversal size D and/or the focal length F from the rest of the plurality of focusing elements 112. In various implementations, the distance between the plurality of focusing elements 112 and the rearward surface of the light collector 106 can be less than the focal length F such that ambient light focused by the plurality of focusing elements 112 is directed out of the light collector 106.

In the implementation illustrated in FIGS. 1A-1D, each of the plurality of focusing elements 112 are spaced apart from each other by a gap. In various implementations, each of the plurality of focusing elements 112 can be regularly spaced apart from adjacent focusing elements such that consecutive focusing elements are spaced apart by a uniform distance. For example, in FIG. 1B, the optical axes of focusing elements 112a and 112b, and 112b and 112c are regularly spaced apart by a uniform spacing distance L1. In some implementations, the plurality of focusing elements 112 can be irregularly spaced apart from adjacent focusing elements such that consecutive focusing elements are spaced apart by a non-uniform distance. Implementations including irregularly spaced apart focusing elements can be advantageous to reduce Moiré fringes. In various implementations, the spacing distance between adjacent focusing elements of the plurality of focusing elements 112 can greater than, equal to, or less than the transversal size D. In various implementations, spacing distance between adjacent focusing elements of the plurality of focusing elements 112 can be between 0.1 mm and 25 mm. Ambient light that is incident on the gaps between adjacent focusing elements (or the region of the light collector that is devoid of focusing elements) is transmitted through the light collector 106 and is not collected by the light collector 106. The spacing between adjacent focusing elements can be selected during manufacturing to vary the light collection efficiency and the transmission through the light collector 106 to a desired level. For example, when the spacing between adjacent focusing elements is reduced, the light collection efficiency of the light collector 106 is increased while the transmission through the light collector 106 is decreased. Conversely, when the spacing between adjacent focusing elements is increased, the light collection efficiency of the light collector 106 is decreased while the transmission through the light collector 106 is increased.

In the implementation illustrated in FIGS. 1A-1D, the plurality of light redirecting elements 114 are disposed on the rearward surface 109 of the light guide 107. However, in various implementations, the plurality of light redirecting elements 114 can be disposed on the forward surface of the light guide 107. In some implementations, the light guide 107 can include a substrate and a film or a plate provided with the plurality of light redirecting elements 114 can be adhered or attached to the substrate. In various implementations, the plurality of light redirecting elements 114 can be manufactured using methods such as etching, embossing, imprinting, lithography, etc. In some implementations, the plurality of light redirecting elements 114 can include white paint that is applied to the forward or rearward surfaces of the light guide 107.

The plurality of light redirecting elements 114 can include grooves that extend into the light guide 107. The grooves can have a depth dimension d that extends into the rearward surface 109 of the light guide 107. In various implementations, the depth dimension d of each groove can have a value between approximately 0.001 mm to approximately 3 mm. In various implementations, the plurality of light redirecting elements 114 can include linear grooves, elongated grooves, v-grooves, scattering features, optical refractive, reflective or diffractive features. In various implementations, the plurality of redirecting elements 114 can include v-grooves having non-linear extent. For example, the axis of the v-grooves may be curved (e.g., circular or elliptical). V-grooves having non-linear extent may be advantageous to collect diffused ambient light, for example, under cloudy conditions. V-grooves arranged along curved paths may be also advantageous in focusing the ambient light. In various implementations, the side walls of V-grooves can be a generic quadratic curve, or a portion of a quadratic curve. For example, the side walls can be elliptical, parabolic, hyperbolic or other higher order aspheric curves. V-grooves with curved sidewalls can have optical power to focus and/or concentrate the ambient light. In various implementations, the grooves can have a non-linear turning surface having a surface normal that is tilted with respect to a normal to the light guide 107 to efficiently collect off-axis light. In various implementations, some of the plurality of light redirecting elements 114 can be linear v-grooves including planar facets that are arranged at an angle θ with respect to each other. The angle between the planar facets can be between approximately 20 degrees and approximately 150 degrees. In various implementations, some of the plurality of light redirecting elements 114 can include two or more turning features. The turning features can include prismatic features, diffractive features, refractive features, reflective features, scattering features, holographic features, etc.

In various implementations, each of the plurality of light redirecting elements 114 can correspond to one of the plurality of focusing elements 112. In various implementations, each of the plurality of light redirecting elements 114 can be registered with a corresponding focusing element such that the light redirecting element is aligned with a focal point of the corresponding focusing element. In various implementations, each of the plurality of focusing elements 112 may not have a corresponding light redirecting element. In implementations including linear v-grooves, each linear v-groove can be aligned with respect to a corresponding focusing element such that an apex of each linear v-groove coincides or is vertically aligned with the optical axis of the corresponding focusing element. In other implementations, the apex of each linear v-groove can be offset from the optical axis of the corresponding focusing element. The offset distance can depend on the latitude of the geographical location where the device is located. In various implementations, the offset distance can be between approximately 0.01 mm and 0.5 mm. In some implementations, two or more light redirecting elements can be vertically aligned with the optical axis of one focusing element such that light focused by the focusing element is incident on the two or more light redirecting elements and subsequently redirected towards the PV cells 110a-110d by the two or more light redirecting elements.

In various implementations, the plurality of light redirecting elements 114 can be spaced apart from each other such that a region that is devoid of light redirecting elements is included between the plurality of light redirecting elements 114. In various implementations, the spacing between adjacent light redirecting elements can be aligned with the spacing between adjacent focusing elements such that light that is transmitted through the light collector 106 is also transmitted through the light guide 107 to the region rearward of the first optical structure 101. For example, as shown in FIG. 1C, the location of the gaps between light redirecting elements 114a and 114b, and 114b and 114c coincide with the location of the gaps between focusing elements 112a and 112b, and 112b and 112c. In various implementations, the gap distance g1 between adjacent redirecting elements 114a and 114b can be equal to the gap distance L1 between adjacent focusing elements 112a and 112b. In various implementations, each of the plurality of light redirecting elements 114 can be regularly spaced apart from adjacent light redirecting elements such that consecutive light redirecting elements are spaced apart by a uniform distance.

In some implementations, each of the plurality of light redirecting elements 114 can be irregularly spaced apart from adjacent light redirecting elements such that consecutive light redirecting elements are spaced apart by a non-uniform distance. For example, in some implementations, the spacing between adjacent light redirecting elements may be increased closer to the edges of the light guide 107 and the spacing between adjacent light redirecting elements may be decreased in the central portion of the light guide 107. In various implementations, the spacing between consecutive light redirecting elements can be between 0.1 mm and 25 mm. In various implementations, adjacent light redirecting elements can be disposed to abut each other such that there is no gap between adjacent light redirecting elements. The spacing between each of the plurality of light redirecting elements 114 can be selected to vary the light collection efficiency and the transmissivity of the light guide 107. For example, when the spacing between adjacent light redirecting elements is reduced, the transmissivity of the light guide 107 is decreased. Conversely, when the spacing between adjacent light redirecting elements is increased, the transmissivity of the light guide 107 is increased. The spacing between light adjacent redirecting elements can also affect the light guiding efficiency. For example, if the spacing between adjacent light redirecting elements is decreased, light propagating through the light guide 107 can suffer scattering losses due to repeated interaction with the plurality of redirecting features, thereby, decreasing the light guiding efficiency.

As discussed above, the second optical structure 115 includes a plurality of light redirecting elements 117. In the implementation illustrated in FIGS. 1A-1D, the plurality of light redirecting elements 117 are disposed on the forward surface 116a of the second optical structure 115. However, in various implementations, the plurality of light redirecting elements 117 can be disposed on the rearward surface 116b of the second optical structure 115. Where appropriate, structures and features of the plurality of light redirecting elements 114 discussed above may be incorporated into the plurality of light redirecting elements 117. For example, the plurality of light redirecting elements 117 can include grooves that extend into the second optical structure 115. In various implementations, the plurality of light redirecting elements 117 can include linear grooves, elongated grooves, v-grooves, scattering features, optical refractive, reflective or diffractive features, v-grooves having non-linear extent, v-grooves arranged along curved paths, v-grooves with curved sidewalls, linear v-grooves including planar facets, prismatic features, trapezoidal shaped redirecting elements, white paint that scatter light, etc.

In various implementations, the plurality of light redirecting elements 117 can be disposed on or over the forward and rearward surfaces 116a and 116b of the second optical structure 115. In various implementations, the second optical structure 115 can include a substrate. A film or a plate provided with the plurality of light redirecting elements 117 can be disposed with respect to the substrate, for example, the film or the substrate can be adhered to, or attached to, the substrate. In various implementations, the plurality of light redirecting elements 117 can be manufactured using methods such as etching, embossing, imprinting, lithography, etc. In some implementations, the plurality of light redirecting elements 117 can include white paint that is applied to the forward or rearward surfaces of the second optical structure 115.

Similar to the configuration of the plurality of light redirecting elements 114, the plurality of light redirecting elements 117 can be spaced apart from each other such that a region that is devoid of light redirecting elements is included between the plurality of light redirecting elements 117. In various implementations, each of the plurality of light redirecting elements 117 can be regularly spaced apart from adjacent light redirecting elements such that consecutive light redirecting elements are spaced apart by a uniform distance. In some implementations, each of the plurality of light redirecting elements 117 can be irregularly spaced apart from adjacent light redirecting elements such that consecutive light redirecting elements are spaced apart by a non-uniform distance. In various implementations, the spacing between adjacent light redirecting elements 117a, 117b and 117c can be aligned with the spacing between adjacent light redirecting elements 114a, 114b and 114c (or the spacing between adjacent focusing elements 112a, 112b and 112c) such that light that is transmitted through the light collector 106 and light guide 107 is also transmitted through the second optical structure 115 to regions rearward device 100. In this way, the device 100 can be configured to provide natural lighting and/or to vary the visibility through the device 100. In various implementations, the spacing between adjacent light redirecting elements can be increased closer to the edges of the second optical structure 115 and decreased in the central portions of the second optical structure 115 to provide uniform illumination across the entire second optical structure 115. The spacing between adjacent redirecting elements 117a, 117b, and 117c can be selected to vary the light transmission, light guiding efficiency and/or the light turning efficiency.

Ambient light that is incident on the forward surface 108 of the light collector 106 is focused by each of the plurality of focusing elements 112 and directed out of the light collector 106 as a focused beam of light. The light guide 107 and the plurality of light redirecting elements 114 included in the light guide 107 are disposed relative to the light collector 106 such that focused beam of light from each of the plurality of focusing elements 112 is incident onto a corresponding light redirecting element from the plurality of light redirecting elements 114. Each of the plurality of light redirecting elements 114 is configured to divert or turn the focused beam of light incident thereon towards the one of the PV cells 110a-110d. The focused beam of light that is diverted by the plurality of light redirecting elements 114 propagate through the light guide 107 by successive total internal reflections of the forward surface and the rearward surface 109 of the light guide 107 towards the PV cells 110a-110d. The plurality of focusing elements 112 and the plurality of light redirecting elements 114 can be configured such that a portion of ambient light that is incident on the forward surface 108 of the light collector 106 is transmitted out of the light guide 107 through the rearward surface 109. In various implementations, approximately 1% to approximately 30% of the ambient light that is incident on the forward surface 108 of the light collector 106 is diverted towards the one or more PV cells 110a-110d. In various implementations, approximately 1% to approximately 30% of the ambient light that is incident on the forward surface 108 of the light collector 106 is transmitted through the light collector 106 and the light guide 107. Referring to FIG. 1D, rays 125 and 135 are representative of ambient light that is focused by the plurality of focusing elements 112 and redirected by the plurality of light redirecting elements 114 towards the PV cells 110a, and 110c respectively. Still referring to FIG. 1D, rays 130 and 140 are representative of the portion of ambient light that is incident on the forward surface 108 of the light collector 106 and transmitted out of the rearward surface 109 of the light guide 107.

Light from the one or more sources of illumination 120a-120d that is injected into the edges of the second optical structure 115 propagates through the second optical structure 115 by successive total internal reflections from the forward surface 116a and the rearward surface 116b of the second optical structure 115. Here the second optical structure 115 functions as a light guide. The plurality of the light redirecting elements 117 disrupt the total internal reflection of the propagating light such that light from the one or more sources of illumination 120a-120d is directed out of the second optical structure 115 when it strikes one or some of the plurality of light redirecting elements 117. In this way, the second optical structure 115 is configured to provide artificial lighting. Referring to FIG. 1D, rays 145, 150, 160 and 165 are representative of light from the sources of illuminations 120a, and 120c that is directed out of the second optical structure 115.

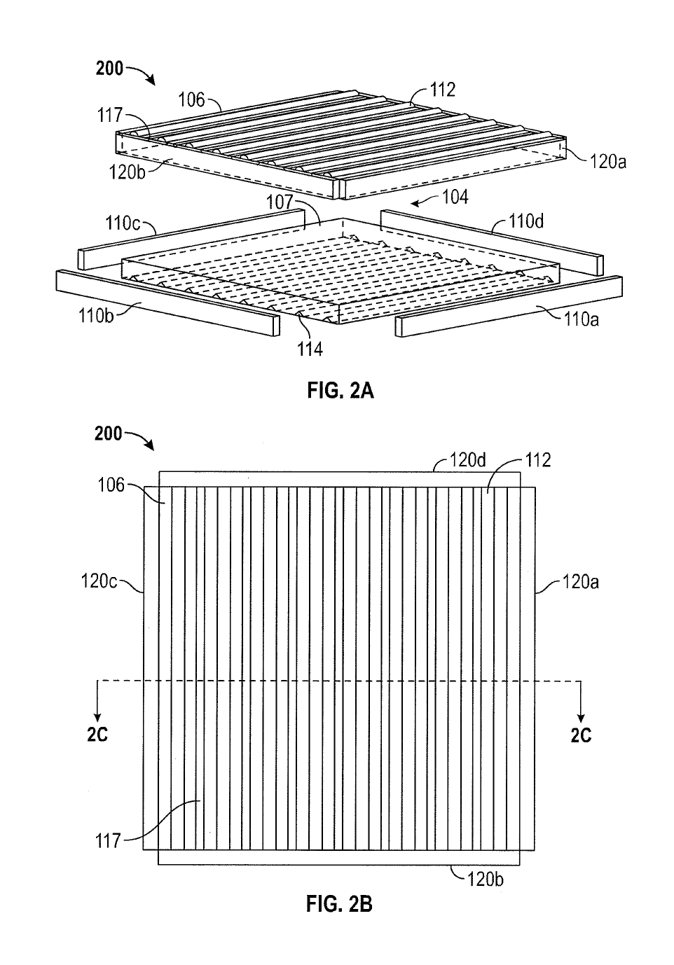

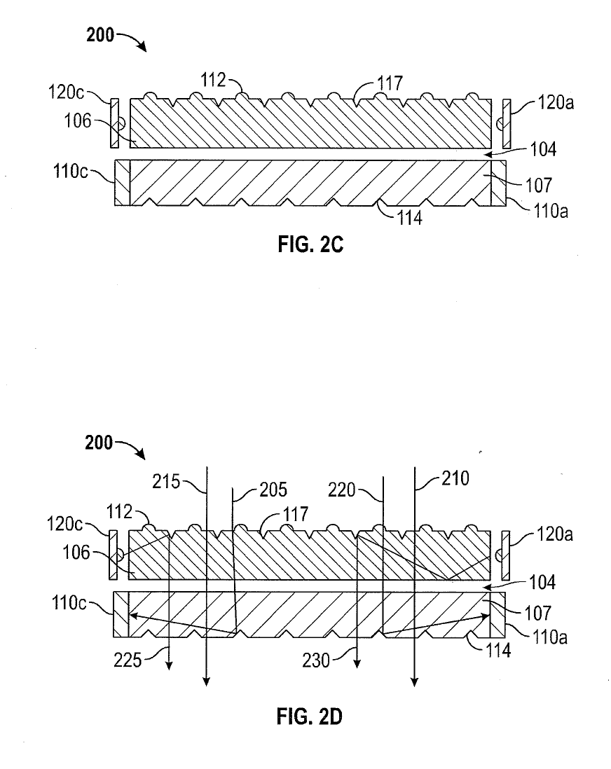

In various implementations of the PV power generating luminaire, elements of the second optical structure 115 can be combined with the light collector 106 or the light guide 107 such that the first optical structure 101 can be used to generate PV power and simultaneously provide artificial lighting. A possible advantage of combining the elements of the second optical structure 115 with the first optical structure 101 is reduction in the thickness and mass of the PV power generating luminaire. The implementations illustrated in FIGS. 2A-8D show different ways of combining the elements of the second optical structure 115 with the first optical structure 101. Where appropriate, structures and features of the light collector 106, light guide 107, plurality of redirecting elements 114 and 117, PV cells 110a-110d and one or more source of illumination 120a-120d discussed above with reference to FIGS. 1A-1D may be incorporated into the implementations illustrated in FIGS. 2A-8D and discussed below in further detail.

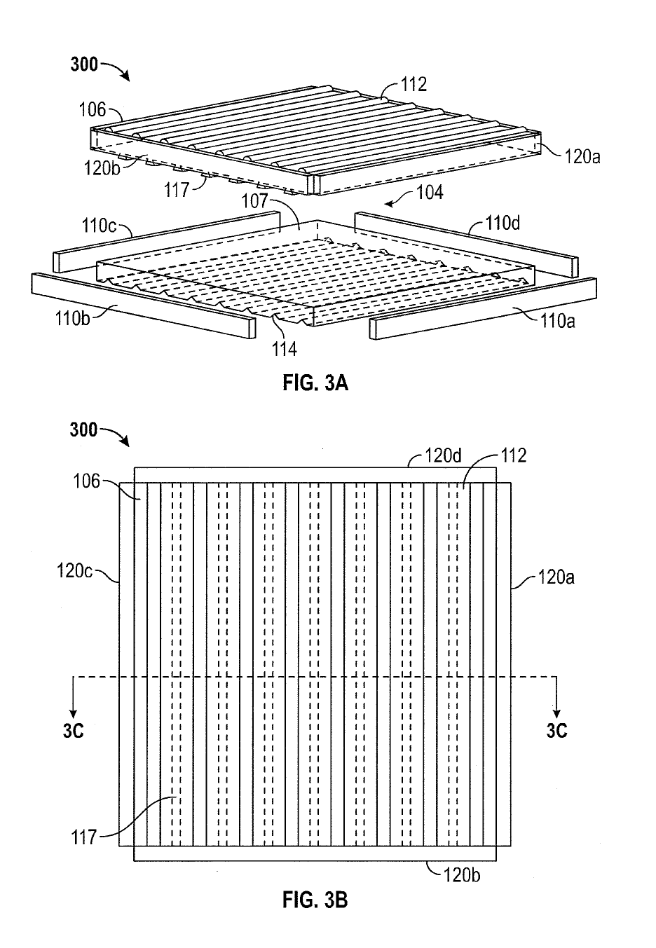

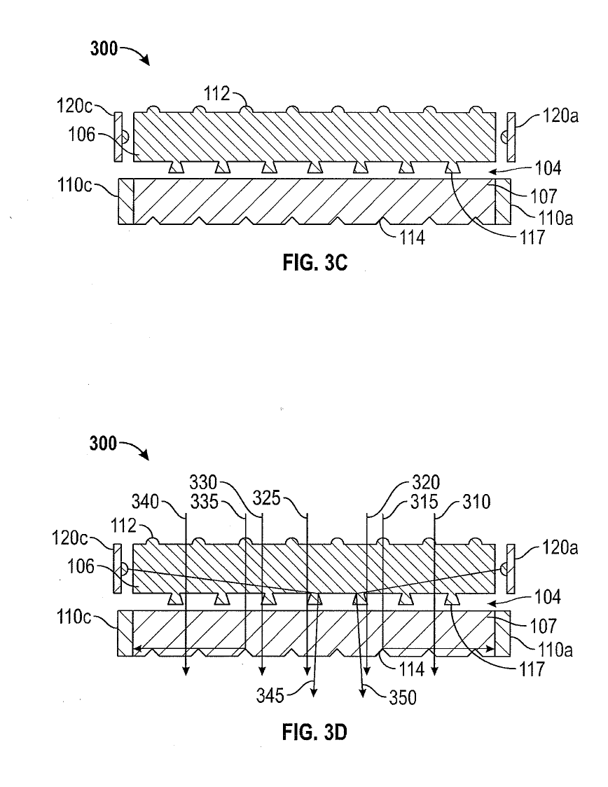

FIGS. 2A and 3A illustrate a perspective view of two different implementations 200 and 300 of a device including a light collector 106 that is optically coupled to one or more sources of light 120a and 120b and a light guide 107 that is optically coupled to one or more PV cells 110a-110d, the light collector 106 having a plurality of optical focusing elements 112 and light redirecting elements 117 and the light guide 107 including a plurality of light redirecting elements 114. FIG. 2B is a top view of the implementation depicted in FIG. 2A and FIG. 3B is a top view of the implementation depicted in FIG. 3A. FIGS. 2C and 2D illustrate the side view of the implementation depicted in FIG. 2A and FIGS. 3C and 3D illustrate the side view of the implementation depicted in FIG. 3A.

The focusing elements 112 included in the light collector 106 in the implementation 200 illustrated in FIGS. 2A-2D and implementation 300 illustrated in FIGS. 3A-3D are half-cylinder shaped lenses. Each of the half-cylinder shaped lenses has a curved surface that is disposed about a cylindrical axis. The curved surface of each half-cylinder shaped lens can have a circular, an elliptical or a parabolic cross-section. Each of the plurality of half-cylinder shaped lenses is designed and oriented to focus incident sunlight along a single line as the sun's position relative to earth changes from east to west during the day. The light redirecting elements 114 provided in the light guide 107 include elongate grooves that are oriented in the same direction as the cylindrical axis of the half-cylinder shaped lenses and positioned at a distance equal to the focal length of the plurality of half-cylinder shaped lenses such that the line along which light is focused by the half-cylinder shaped lenses coincides with the elongate grooves. In such implementations, sunlight focused by each of the half-cylinder shaped lens is incident on a corresponding elongate groove throughout the day. Accordingly, the implementations illustrated in FIGS. 2A-3D can be used to efficiently collect light at various times during the day without actively tracking the diurnal movement of the sun through the sky. As discussed above, focused light that is incident on the light redirecting elements 114 is directed towards the PV cells 110a-110d for PV power generation.

To efficiently collect sunlight throughout the day, the half-cylinder shaped lenses can be positioned such that the plurality of focusing elements 112 are arranged in a north-south orientation. In other words, the cylindrical axis of each half-cylinder shaped lens is oriented generally along the east-west direction such that at noon on an equinox the rays of the sun are incident on the each of the half-cylinder shaped lens along the optical axis of the half-cylinder shaped lens. On other days, the rays of the sun at noon time are incident on the half-cylinder shaped lenses from a direction that is at an angle (plus or minus) with respect to the optical axis of each of the half-cylinder shaped lenses. The angle between the incident direction of sunlight at noon time and the optical axis of each of the half-cylinder shaped lenses can depend on the latitude of the geographical location where the light collector is disposed and the time of the year. When implemented in a window device, the cylindrical axis of the half-cylinder shaped lenses is generally aligned along the same direction as the track of the sun's diurnal movement. This can advantageously allow the window device to collect light efficiently at various times during the day and year.

In implementations 200 and 300 illustrated in FIGS. 2A-2D and 3A-3D respectively, the one or more sources of light 120a-120d are disposed along the edges included between the forward surface 108 and the rearward surface of the light collector 106. In addition to including focusing elements 112, the light collector 106 also includes the plurality of light redirecting elements 117 that are configured to redirect light from the one or more sources of light 120a-120d propagating through the light collector 106 out of the light collector 106 to provide artificial lighting. Because the light collector 106 is configured to provide artificial lighting in addition to collecting ambient light for PV power generation, the second optical structure 115 can be eliminated.

In the implementation 200 illustrated in FIGS. 2A-2D, the light redirecting elements 117 include triangular grooves that protrude into the forward surface 108 of the light collector 106. The light redirecting elements 117 of the implementation 300 illustrated in FIGS. 2A-2D are trapezoidal shaped projections that protrude out of the rearward surface of the light collector 106. The trapezoidal shaped projections may be advantageous in reducing scattering losses due to the shallow slope of the edges. Another possible advantage presented by the trapezoidal shaped projections may be ease of manufacturing. The light collector 106 and the light guide 107 can include regions that are devoid of any focusing or redirecting element such that ambient light that is incident on the forward surface 108 of the light collector 106 is transmitted through the light collector 106 and the light guide 107 in the implementations 200 and 300 illustrated in FIGS. 2A-3D.

Referring to FIG. 2D, rays 210 and 215 are representative of incident ambient that is transmitted through the light collector 106 and the light guide 107; rays 220 and 205 are representative of incident ambient that is diverted by the redirecting elements 114 towards the PV cells 110a and 110c respectively; and rays 225 and 230 are representative of light from the sources of illumination 120a and 120b that are directed out of the light collector 106 and the light guide 107 by the redirecting elements 117.

Referring to FIG. 3D, rays 310, 320, 325 and 340 are representative of incident ambient that is transmitted through the light collector 106 and the light guide 107; rays 315 and 335 are representative of incident ambient that is diverted by the redirecting elements 114 towards the PV cells 110a and 110c respectively; and rays 345 and 350 are representative of light from the sources of illumination 120a and 120b that are directed out of the light collector 106 and the light guide 107 by the redirecting elements 117.

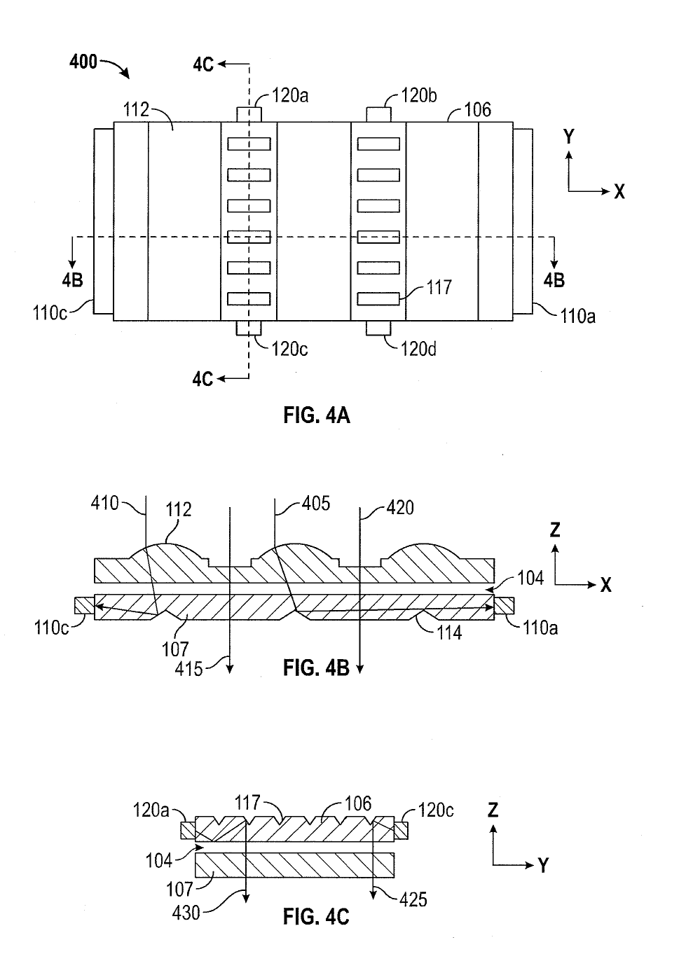

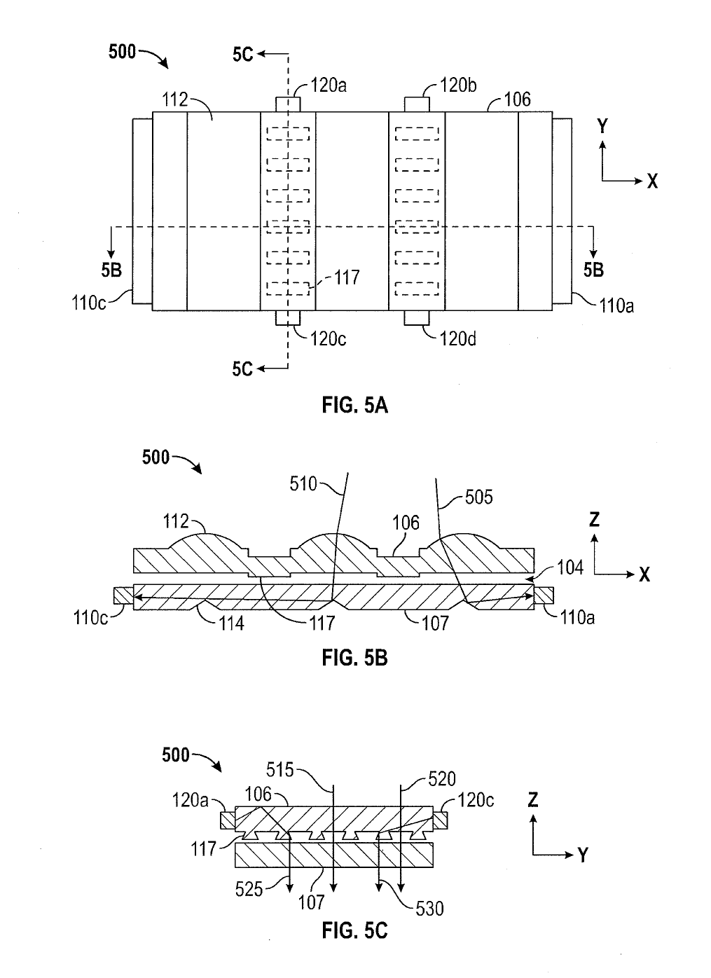

FIGS. 4A and 5A illustrate top view of two different implementations 400 and 500 of a device including a light collector 106 that is optically coupled to one or more sources of light 120a and 120c and a light guide 107 that is optically coupled to one or more PV cells 110a and 110c, the light collector 106 having a plurality of half-cylinder shaped focusing elements 112 and light redirecting elements 117 having a longitudinal axis that is orthogonal to the cylindrical axis of the half-cylinder shaped focusing elements 112, the light guide 107 including a plurality of light redirecting elements 114. FIG. 4B is a side view of the implementation depicted in FIG. 4A along an axis parallel to the x-axis and FIG. 5B is a side view of the implementation depicted in FIG. 5A along an axis parallel to the x-axis. FIG. 4C is a side view of the implementation depicted in FIG. 4A along an axis parallel to the y-axis and FIG. 5C is a side view of the implementation depicted in FIG. 5A along an axis parallel to the y-axis.

In the implementations 400 and 500 illustrated in FIGS. 4A-5C, the light collector 106 includes a plurality of focusing elements 112. Each of the plurality of focusing elements 112 are half-cylinder shaped lenses that are similar to the lenses described with reference to FIGS. 2A-3D. Ambient light focused by each of the half-cylinder shaped lenses is focused on a plurality of light redirecting elements 114 as discussed above. The focused light incident on each of the plurality of light redirecting elements 114 is diverted such that the diverted light propagates in a direction generally parallel to the x-axis towards the PV cells 110a and 110c. In the illustrated implementations, the light collector 106 also include sources of illumination 120a and 120c whose light emitting surfaces are disposed along a direction that is parallel to the cylindrical axis of the half-cylinder shaped lenses 112. In the illustrated implementations, the sources of illumination 120a and 120c are disposed with respect to the edges of the light collector 106 such that light from the sources of illumination 120a and 120c is injected along a direction parallel to the y-axis. The light collector 106 includes a plurality of light redirecting elements 117. Each of the plurality of light redirecting elements 117 has a longitudinal axis that is parallel to the x-axis and orthogonal to the cylindrical axis of the half-cylinder shaped lenses such that light from the sources of illumination 120a and 120c that is propagating along a direction parallel to the y-axis is directed rearward out of the light collector 106 to provide artificial lighting. The orientation of the plurality of light redirecting elements 117 and the half-cylinder shaped focusing elements 112 can reduce the likelihood that light emitted by the one or more illumination sources 120a and 120c strikes a half-cylinder shaped lens and is refracted out of the device in a non-useful direction. In general the longitudinal axis of the plurality of light redirecting elements 117 can form a non-zero angle with respect to the cylindrical axis of the half-cylinder shaped focusing elements 112.

In the implementation 400 illustrated in FIGS. 4A-4C, the light redirecting elements 117 include triangular grooves that protrude into the forward surface 108 of the light collector 106. The light redirecting elements 117 of the implementation 500 illustrated in FIGS. 5A-5C are trapezoidal shaped projections that protrude out of the rearward surface of the light collector 106. The light collector 106 and the light guide 107 can include regions that are devoid of any focusing or redirecting element such that ambient light that is incident on the forward surface 108 of the light collector 106 is transmitted through the light collector 106 and the light guide 107 in the implementations 400 and 500 illustrated in FIGS. 4A-5C.

Referring to FIGS. 4B and 4C, ray 420 is representative of incident ambient that is transmitted through the light collector 106 and the light guide 107; rays 405 and 410 are representative of incident ambient that is diverted by the redirecting elements 114 towards the PV cells 110a and 110c respectively; and rays 425 and 430 are representative of light from the sources of illumination 120a and 120b that are directed out of the light collector 106 and the light guide 107 by the redirecting elements 117.

Referring to FIGS. 5B and 5C, ray 515 is representative of incident ambient that is transmitted through the light collector 106 and the light guide 107; rays 505 and 510 are representative of incident ambient that is diverted by the redirecting elements 114 towards the PV cells 110a and 110c respectively; and rays 525 and 530 are representative of light from the sources of illumination 120a and 120b that are directed out of the light collector 106 and the light guide 107 by the redirecting elements 117.

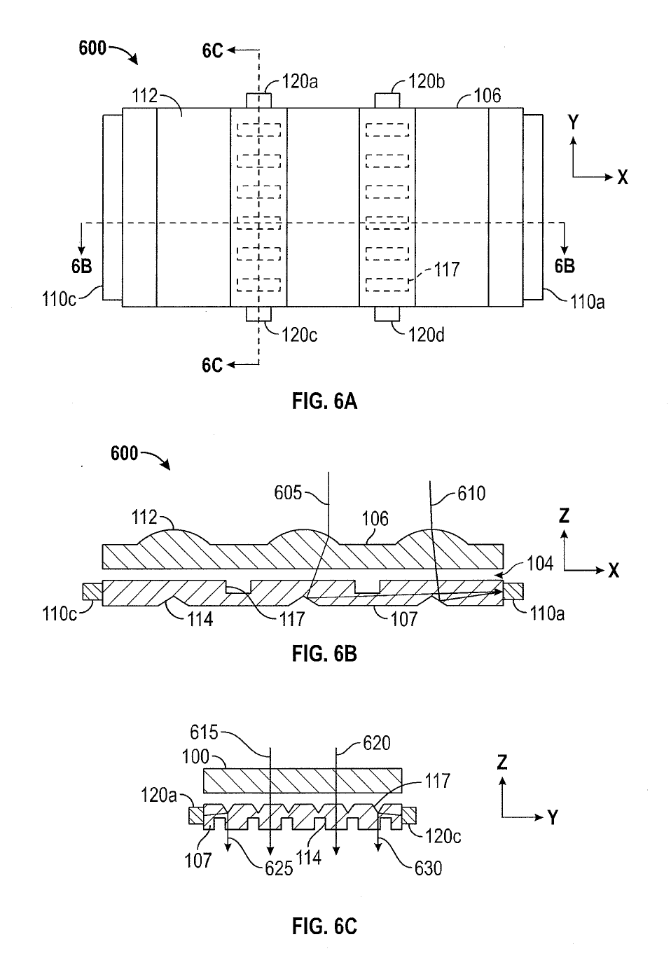

FIG. 6A is a top view of an implementation 600 of a device including a light collector 106 having a plurality of focusing elements 112 and a light guide 107 that is optically coupled to one or more sources of light 120a and 120c and one or more PV cells 110a and 110c having light receiving surfaces disposed along a direction that is orthogonal to direction along which the light emitting surfaces of the one or more sources of light 120a and 120c are disposed, the light guide 107 including a first set of light redirecting elements 114 and a second set of light redirecting elements 117. FIG. 6B is a side view of the implementation 600 depicted in FIG. 6A along an axis parallel to the x-axis. FIG. 6C is a side view of the implementation 600 depicted in FIG. 6A along an axis parallel to the y-axis.

Similar to the implementations 200 and 300 described with reference to FIGS. 2A-3D, the plurality of focusing elements 112 included in the light collector 106 of the implementation 600 illustrated in FIGS. 6A-6C are half-cylinder shaped lenses. The light guide 107 includes a first set of light redirecting elements 114 disposed on the rearward surface of the light guide 107. The first set of light redirecting elements 114 are arranged such that ambient light focused by each of the half-cylinder shaped lenses is focused on a corresponding redirecting element in the first set. Each light redirecting element in the first set is configured to divert the ambient light focused thereon such that the diverted light propagates in a direction generally parallel to the x-axis towards the PV cells 110a and 110c.

The light guide 107 includes sources of illumination 120a and 120c whose light emitting surface are disposed along a direction that is orthogonal to the direction along which the light receiving surfaces of the PV cells 110a and 110c are disposed. In various other implementations, a normal to the light receiving surface of the PV cells 110a and 110c can form a non-zero angle with respect to a normal to the light emitting surface of the illumination sources 120a and 120b. In the illustrated implementation 600, the sources of illumination 120a and 120c are disposed with respect to the edges of the light guide 107 such that light from the sources of illumination 120a and 120c is injected along a direction parallel to the y-axis. The light guide 107 includes a second set of light redirecting elements 117 disposed on the forward surface of the light guide 107. Each light redirecting element in the second set has a longitudinal axis that is parallel to the x-axis such that light from the sources of illumination 120a and 120c that is propagating along a direction parallel to the y-axis is directed rearward out of the light guide 107 to provide artificial lighting.

Referring to FIGS. 6B and 6C, rays 615 and 620 are representative of incident ambient that is transmitted through the light collector 106 and the light guide 107; rays 605 and 610 are representative of incident ambient that is diverted by the first set of light redirecting elements 114 towards the PV cells 110a and 110c respectively; and rays 625 and 630 are representative of light from the sources of illumination 120a and 120b that are directed out of the light guide 107 by the second set of light redirecting elements 117.

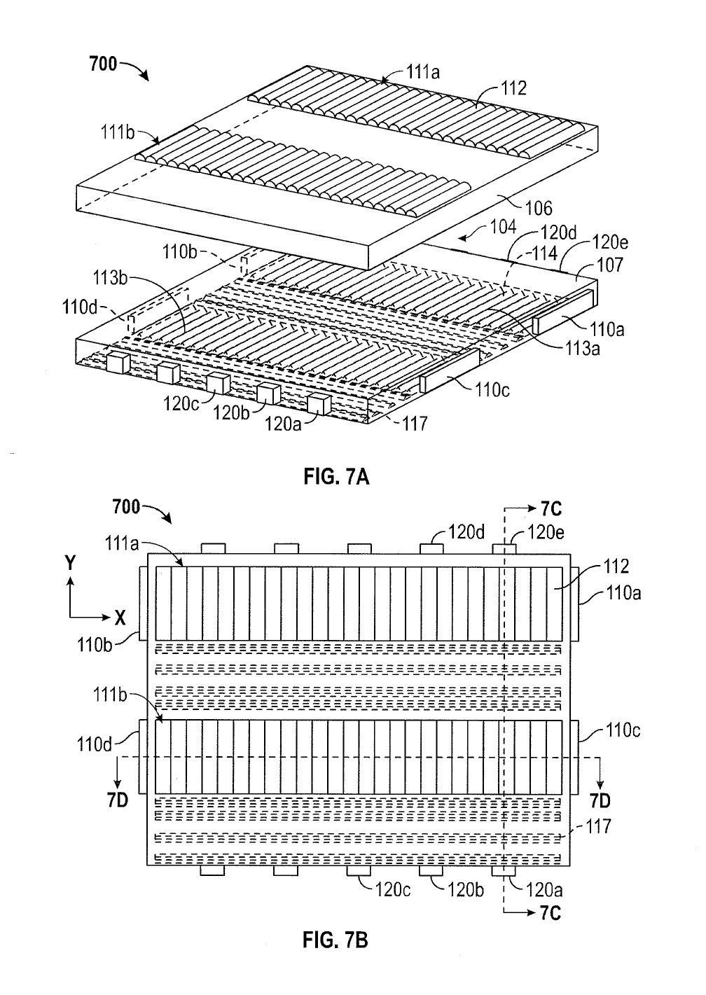

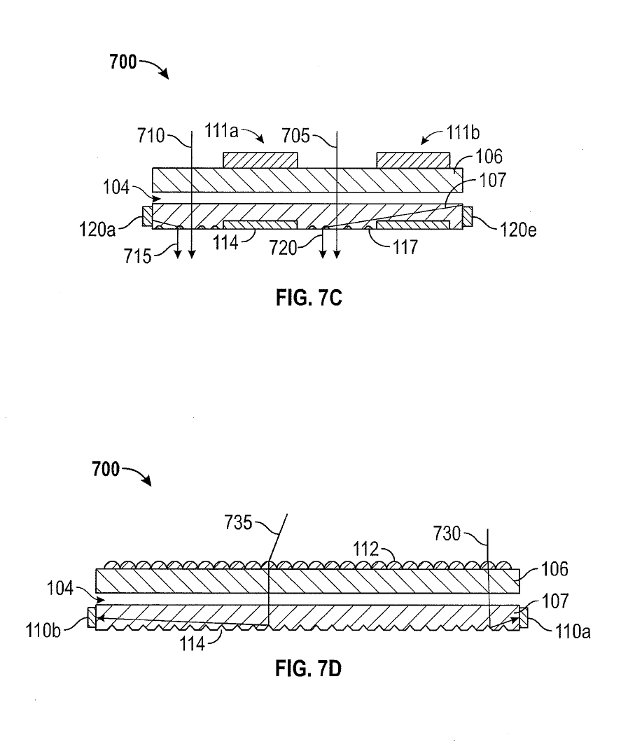

FIG. 7A illustrates a perspective view of an implementation 700 of a device including a light collector 106 having two sets 111a and 111b of focusing elements 112 and a light guide 107 that is optically coupled to one or more sources of light 120a, 120b, 120c and 120e and one or more PV cells 110a, 110b, 110c and 110d having light receiving surfaces disposed along a direction that is orthogonal to the light emitting surfaces of the one or more sources of light 120a, 120b, 120c, 120d and 120e, the light guide 107 including a plurality of light redirecting elements 114 and 117. FIG. 7B is a top view of the implementation depicted in FIG. 7A. FIGS. 7C and 7D illustrate the side view of the implementation depicted in FIG. 7A.

In the illustrated implementation 700, the light collector 106 has a first set 111a of focusing elements 112 and a second set 111b of focusing elements 112. Each focusing element in the first and second sets 111a and 111b is a half-cylinder shaped lense similar to the lenses described above with reference to FIGS. 2A-3D. The light guide 107 includes a first set 113a of light redirecting elements 114, a second set 113b of light redirecting elements 114 and a plurality of light redirecting elements 117. The first set 113a of light redirecting elements 114 are arranged below the first set 111a of focusing elements 112 and the second set 113b of light redirecting elements 114 are arranged below the second set 111b of focusing elements 112. As discussed above, the first set 113a and the second set 113b of light redirecting elements 114 are arranged such that the longitudinal axis of each of the redirecting elements 114 in the first set 113a and the second set 113b are parallel to the cylindrical axis of each of the plurality of focusing elements 112 in the first and second sets 111a and 111b. Ambient light is focused by each of the plurality of focusing elements 112 in the first and second sets 111a and 111b onto a corresponding light redirecting element in the first and second sets 113a and 113b. Each light redirecting element is configured to divert the focused light incident thereon towards the one or more PV cells 110a-110d disposed along the edges of the light guide 107. The light diverted by the plurality of light redirecting elements 114 in the two sets 113a and 113b propagates by multiple total internal reflections through the light guide 107 along a direction generally parallel to the x-axis.

One or more sources of illumination 120a-120e are disposed along the edges that are adjacent the edges along which the PV cells 110a-110d are disposed. Accordingly, the light emitting surfaces of the one or more sources of illumination 120a-120e are disposed along a direction that is orthogonal to the direction along which the light receiving surfaces of the PV cells 110a-110d are disposed. In various implementations, a normal to the light emitting surface of the one or more sources of illumination 120a-120e can form a non-zero angle with respect to a normal to the light receiving surface of the PV cells 110a-110d. In the illustrated implementation, light emitted by the one or more sources of illumination 120a-120e generally propagates through the light guide 107 along a direction parallel to the y-axis by total internal reflection from the forward and rearward surfaces of the light guide 107. The plurality of light redirecting elements 117 are arranged such that the light from the one or more sources of illumination 120a-120e propagating through the light guide 107 is directed out of the light guide 107 upon interaction with one of the plurality of light redirecting elements 117. In some implementations, the light redirecting elements 114 in the first and second sets 113a and 113b can be disposed on the rearward surface of the light guide 107 and the plurality of light redirecting elements 117 can be disposed on the forward surface of the light guide 107. Conversely as depicted in the illustrated implementation, the light redirecting elements 114 in the first and second sets 113a and 113b and the plurality of light redirecting elements 117 can be disposed on the rearward surface of the light guide 107. In such implementations, the light redirecting elements 114 in the first and second sets 113a and 113b and the plurality of light redirecting elements 117 are laterally offset from one another. In this way, half of the bottom plate can provide artificial and natural light into the interior of a building and the other half can collect natural light for the one or more PV cells 110a-110d. Thus, a light output aperture of the luminaire can be less than a natural light input aperture of the device.

Referring to FIGS. 7C and 7D, rays 705 and 710 are representative of incident ambient light that is transmitted through the light collector 106 and the light guide 107; rays 730 and 735 are representative of incident ambient light that is diverted by the light redirecting elements 114 towards the PV cells 110a and 110c respectively; and rays 715 and 720 are representative of light from the sources of illumination 120a and 120e that are directed out of the light guide 107 by light redirecting elements 117.

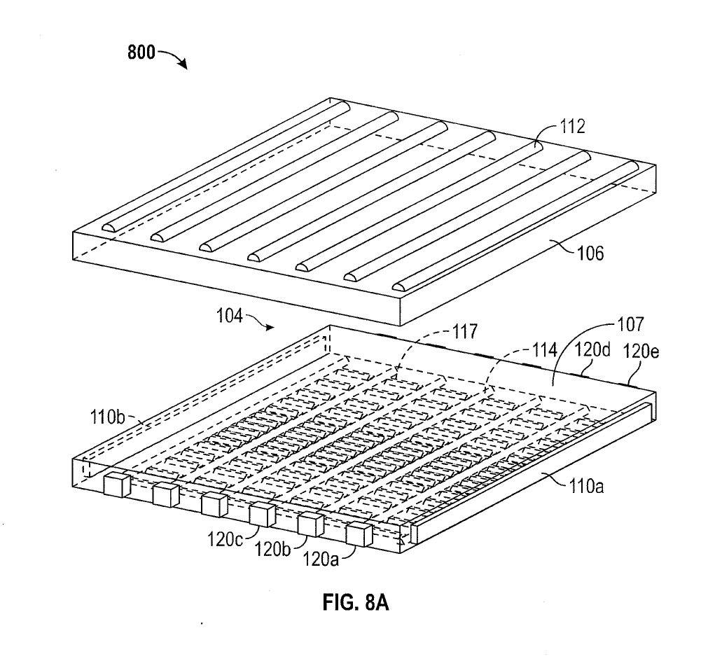

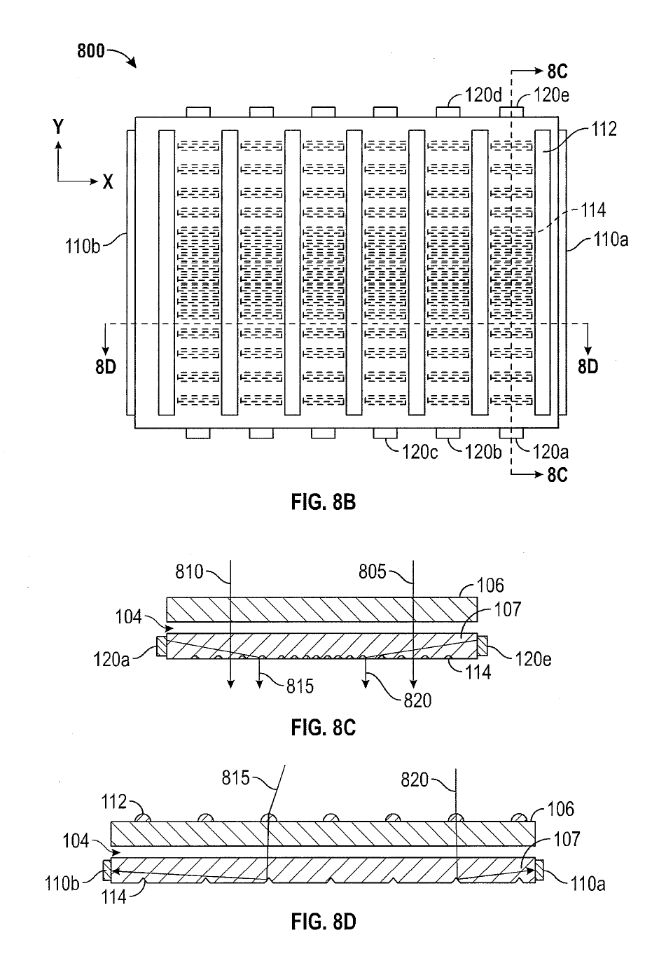

FIG. 8A illustrates a perspective view of an implementation 800 of a device including a light collector 106 having a plurality focusing elements 112 and a light guide 107 including a first of set of redirecting elements 114 and a second set of light redirecting elements 117, the second set of light redirecting elements 117 having a varying density. FIG. 8B is a top view of the implementation depicted in FIG. 8A. FIGS. 8C and 8D illustrate the side view of the implementation depicted in FIG. 8A.

In the implementation illustrated in FIG. 8A, the plurality of focusing elements 112 includes half-cylinder shaped lenses similar to the lenses described with reference to FIGS. 2A-3D. The plurality of light redirecting elements 114 are arranged such that ambient light focused by each of the half-cylinder shaped lens is incident on a corresponding light redirecting element and redirected towards PV cells 110a and 110b disposed along the edges of light guide 107.

As illustrated in FIG. 8A, one or more illumination sources 120a, 120b, 120c, 120d, and 120e are disposed along the edges of the light guide 107 that are adjacent the edges along which the PV cells 110a and 110b are disposed. Accordingly, in the illustrated implementation, the light receiving surfaces of the PV cells 110a and 110b are orthogonal to the light emitting surfaces of the one or more illumination sources 120a-120e. In various other implementations, a normal to the light receiving surface of the PV cells 110a and 110b can form a non-zero angle with respect to a normal to the light emitting surface of the one or more illumination sources 120a-120e. In the illustrated implementation, light emitted by the one or more illumination sources 120a-120e propagates along a direction generally parallel to the y-axis. The plurality of redirecting elements 117 are arranged such that the light from the one or more illumination sources 120a-120e propagating through the light guide 107 is directed out of the light guide 107 upon interaction with one of the plurality of light redirecting elements 117.

In the implementation illustrated in FIG. 8A, the fill factor (or the density) of the plurality of light redirecting elements 117 is non-uniform across the light guide 107. In this implementation, the fill factor of the plurality of light redirecting elements 117 is less at the edges of the light guide 107 along which the one or more illumination sources 120a-120d are disposed. Conversely, the density, or fill factor, of the plurality of light redirecting elements 117 is greater in the central portion of the light guide 107. In various implementations, the intensity of light near the edges of the light guide 107 along which the one or more illumination sources 120a-120d are disposed can be greater than in the central portion of the light guide 107. In such implementations, having fewer light redirecting elements 117 near the edges as compared to the central portion can be advantageous in achieving uniform illumination. In some implementations, the plurality of light redirecting elements 114 can be disposed on the rearward surface of the light guide 107 and the plurality of light redirecting elements 117 can be disposed on the forward surface of the light guide 107. Conversely as depicted in the illustrated implementation, the plurality of light redirecting elements 114 and the plurality of light redirecting elements 117 can be disposed on the rearward surface of the light guide 107. In such implementations, the plurality of light redirecting elements 114 and the plurality of light redirecting elements 117 are laterally offset from each another.

Referring to FIGS. 8C and 8D, rays 805 and 810 are representative of incident ambient light that is transmitted through the light collector 106 and the light guide 107; rays 825 and 830 are representative of incident ambient light that is diverted by the light redirecting elements 114 towards the PV cells 110a and 110c respectively; and rays 815 and 820 are representative of light from the sources of illumination 120a and 120e that are directed out of the light guide 107 by light redirecting elements 117.

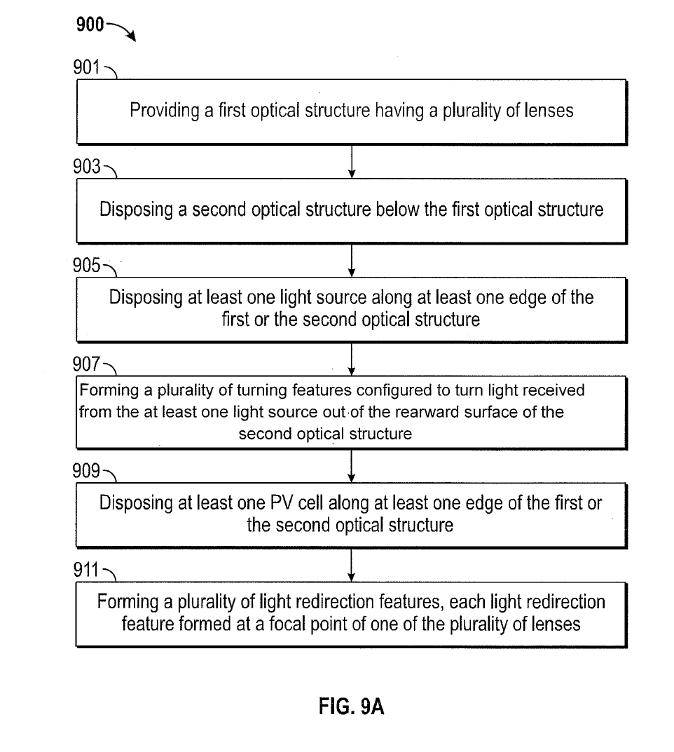

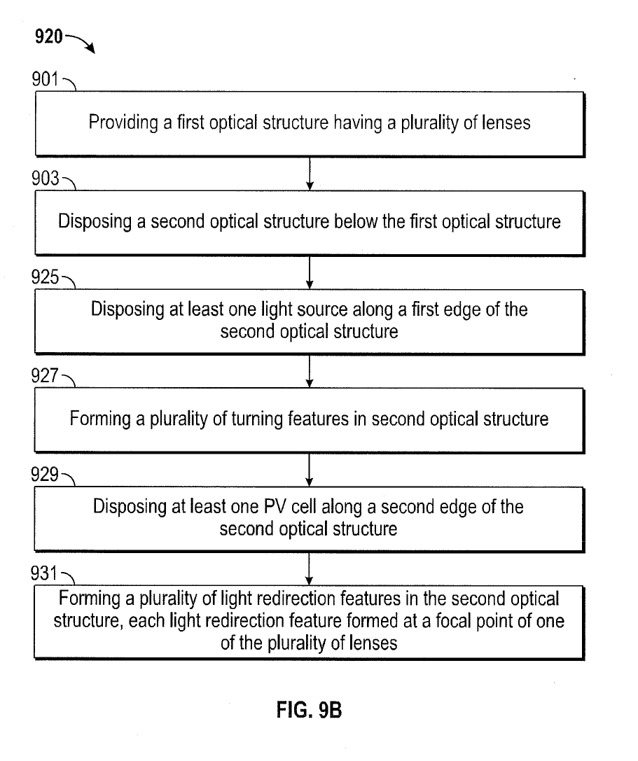

FIGS. 9A and 9B are flow charts illustrating two different examples of a method of manufacturing an implementation of a PV power generating luminaire similar to the implementations 100, 200, 300, 400, 500, 600, 700 and 800 described above. The methods 900 and 920 include providing a first optical structure having a plurality of lenses as shown in block 901. The first optical structure can be similar to the light collector 106 or the first optical structure 101 discussed above. The plurality of lenses can be similar to the plurality of focusing elements 112 described above. In various implementations, the plurality of lenses can include half-cylinder shaped lenses that are arranged parallel to each other and extend across the forward surface of the first optical structure. The methods 900 and 920 further include disposing a second optical structure below the first optical structure as shown in block 903. The second optical structure can be similar to the light guide 107 or the second optical structure 115 discussed above.

Referring to FIG. 9A, the method 900 then proceeds to block 905 including disposing at least one light source along an edge of the first or the second optical structure. The at least one light source can be similar to the one or more sources of illumination 120a-120e. In block 907 of the method 900 a plurality of turning features are formed. The turning features can be similar to the light redirecting elements 117 described above and are configured to turn light received from the at least one light source out of the rearward surface of the second optical structure. The turning features can be formed such that each turning feature is vertically aligned with a focal point of a lens from the plurality of lenses. In various implementations, forming the plurality of turning features includes forming triangular/trapezoidal shaped prismatic features that extend across the forward surface of the first optical structure. In various implementations, the plurality of turning features can be parallel to each other. In various implementations, the plurality of turning features can be formed between the plurality of lenses. In block 909 at least one PV cell is disposed along at least one edge of the first or the second optical structure. The at least one PV cell can be similar to the one or more PV cells 110a-110d described above. The method then proceeds to forming a plurality of light redirection features as shown in block 911. The plurality of light redirection features can be similar to the light redirecting elements 114 described above. Each light redirection feature is formed at a focal point of one of the plurality of lenses such that light focused by each of the plurality of lenses is focused on a light redirection feature.

Referring to FIG. 9B, the method 920 further includes disposing at least one light source (for example, one or more sources of illumination 120a-120e) along a first edge of the second optical structure as shown in block 925. In block 927 of the method 920 a plurality of turning features (for example, light redirecting elements 117) are formed in the second optical structure. The turning features are configured to turn light received from the at least one light source out of the rearward surface of the second optical structure. The turning features can be formed such that each turning feature is vertically aligned with a focal point of a lens from the plurality of lenses. In various implementations, forming the plurality of turning features includes forming triangular/trapezoidal shaped prismatic features that extend across the forward or rearward surface of the second optical structure. In various implementations, the plurality of turning features can be parallel to each other. In various implementations, the a portion of the forward surface of the first optical structure can be devoid of the plurality of lenses and the plurality of turning features can be vertically aligned with the portion of the first optical structure that is devoid of the plurality of lenses. In block 929 at least one PV cell (for example, one or more PV cells 110a-110d) is disposed along a second edge of the second optical structure. The second edge of the second optical structure can be adjacent the first edge of the second optical structure. The method 920 then proceeds to forming a plurality of light redirection features (for example, light redirecting elements 114) in the second optical structure as shown in block 931. Each light redirection feature is formed at a focal point of one of the plurality of lenses such that light focused by each of the plurality of lenses is focused on a light redirection feature.

In various implementations, the methods 900 and 920 can include providing a battery and electrically coupling the at least one PV cell to the battery. In various implementations, the methods 900 and 920 can include electrically coupling the at least one light source to the battery. In various implementations, the methods 900 and 920 can include electrically coupling the at least one PV cell to an electrical grid.

In various implementations, thin films having reflecting, diffracting or scattering features can be disposed forward or rearward of the light collector 106 and/or the light guide 107. The thin films can be used to increase the light collection efficiency, provide visual effects, increase or decrease transmission or to provide other optical function. In various implementations, one or more surfaces of the plurality of light redirecting elements 114 and 117 can include reflecting films or coatings to increase the light collection efficiency or the light extraction efficiency. In some implementations, one or more surfaces of the plurality of light redirecting elements 114 and 117 can include optical films or coatings to achieve different optical effects.

In various implementations, a PV power generating window including the implementations 100, 200, 300, 400, 500, 600, 700 and 800 can be obtained by assembling the first optical structure 101 and the second optical structure 115 in a frame including electrical connections. In various implementations, the electrical connection may be embedded in the light collector 106 or the light guide 107. In various implementations, the one or more sources of illumination 120a-120e can be powered by energy generated by the PV cells 110a-110d of the device. For example, the PV cells of 110a-110d of the device can be electrically coupled to a battery configured to store energy generated by the PV cells 110a-110d, and the one or more sources of illumination 120a-120e can be electrically coupled to the battery. Accordingly, the device may provide artificial light and may provide at least some, if not all, of the energy required to power the artificial light source(s). In some implementations, the device may be “on the grid” such that excess energy can be distributed to the grid. Implementations of a PV power generating luminaire including the implementations 100, 200, 300, 400, 500, 600, 700 and 800 can provide an aesthetically pleasing appearance, can efficiently collect and divert sunlight to one or more PV cells at various times during the day, provide artificial lighting and have a varying degree of transmissivity. Various implementations of a PV power generating luminaire including the implementations 100, 200, 300, 400, 500, 600, 700 and 800 can have a visual effect comparable to or better than a window screen.

The above-described implementations and other similar implementations can be used as a (building-integrated photovoltaic) BIPV product (for example, window, skylight, facade, door, glazing, or a curtain wall). A BIPV product using a device similar to those described herein can reduce the cost of the BIPV product since the PV cells are used only at the edges of the device (for example, first optical structure 101 or the light guide 107). High efficiency Si or III-V solar cells can be used in various implementations to increase the photoelectric conversion efficiency. A BIPV product using a device similar to those described herein can additionally reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement; be compatible with curved glass windows and be aesthetically pleasing as conventional windows. Additionally, a BIPV product using a device similar to those described herein can be used for windows, privacy screens, skylights, etc. A BIPV product using a device similar to those described herein can be used to generate PV power efficiently at various times during the day and also provide natural and/or artificial lighting.

Various implementations of the devices described herein can be used to efficiently generate PV power and provide artificial lighting. The devices described herein can be relatively inexpensive, thin and lightweight. The devices described herein including light collectors and light guides with focusing elements and light redirecting elements and coupled to one or more PV cells and one or more illumination sources can be used in a variety of applications. For example, various implementations of devices described herein can be configured as building-integrated photovoltaic products such as, for example, windows, roofs, skylights, facades, etc. to generate PV power and provide artificial lighting. In other applications, various implementations of devices described herein may be mounted on automobiles and laptops to provide PV power and artificial light. Various implementations of the devices described herein can be mounted on various transportation vehicles, such as aircrafts, trucks, trains, bicycles, boats, etc.

Implementations 100, 200, 300, 400, 500, 600, 700 and 800 discussed above including a plurality of focusing elements and a plurality of light redirecting features that are optically coupled to PV cells and one or more sources of illumination may have an added advantage of being modular. For example, depending on the design, the PV cells may be configured to be removably attached. Thus existing PV cells can be replaced periodically with newer and more efficient PV cells without having to replace the entire system. This ability to replace PV cells may reduce the cost of maintenance and upgrades substantially.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a first optical structure having a plurality of lenses, each lens being configured to focus light incident on the lens toward a focal point disposed below the plurality of lenses, the first optical structure having a forward surface and a rearward surface;
a second optical structure disposed below the first optical structure, the second optical structure having a forward surface, a rearward surface, a first edge extending between the rearward surface and the forward surface of the second optical structure, and a second edge extending between the rearward surface and the forward surface of the second optical structure;
at least one light source disposed along the first edge of the second optical structure;
a plurality of turning features disposed in the second optical structure configured to turn light received from the at least one light source out of the rearward surface of the second optical structure;
at least one photovoltaic cell disposed along the second edge of the second optical structure; and
a plurality of light redirection features each disposed in the second optical structure at a focal point of one of the plurality of lenses, the plurality of light redirection features configured to redirect at least a portion of light focused by the plurality of lenses toward the at least one photovoltaic cell.

2. The device of claim 1, wherein the second optical structure is offset from the first optical structure by a separating layer having a refractive index lower than a refractive index of the second optical structure.

3. The device of claim 2, wherein the separating layer of material includes at least one of air, nitrogen, and argon.

4. The device of claim 1, further comprising a battery electrically coupled to the at least one photovoltaic cell.

5. The device of claim 4, wherein the at least one light source is electrically coupled to the battery.

6. The device of claim 1, wherein the at least one photovoltaic cell is electrically coupled to an electrical grid.

7. The device of claim 1, wherein the plurality of lenses include cylindrical-shaped collection lenses aligned in parallel and extending across the forward or the rearward surface of the first optical structure.

8. The device of claim 7 wherein each light turning feature includes a prismatic feature extending in a direction orthogonal to the alignment of the cylindrical-shaped collection lenses.

9. The device of claim 8, wherein at least one of the light turning features is disposed between at least two of the light redirection features.

10. The device of claim 8, wherein the forward surface of the first optical structure includes a first portion and a second portion, wherein the plurality of lenses are disposed over the first portion of the forward surface, and wherein the plurality of lenses are not disposed over the second portion of the forward surface.

11. The device of claim 10, wherein the light turning features are disposed below the second portion of the forward surface of the first optical structure.

12. The device of claim 1, wherein the plurality of lenses are configured such that approximately 1% to approximately 30% of light that is incident on the first optical structure is re-directed to the at least one photovoltaic cell.

13. A device comprising:
means for focusing at least a portion of light incident on the device toward a plurality of focal points disposed below the light focusing means;
means for guiding light, the light guiding means disposed below the light focusing means and having at least a first edge and a second edge;
at least one photovoltaic cell disposed along the first edge of the light guiding means;
means for redirecting light from the plurality of focal points toward the at least one photovoltaic cell; and
means for providing artificial light from the light guiding means in a direction away from the light focusing means.

14. The device of claim 13, wherein at least a portion of light incident on the device passes through the light focusing means, light redirecting means, and artificial light providing means without being redirected toward the at least one photovoltaic cell.

15. The device of claim 13, wherein the light focusing means includes a plurality of lenses.

16. The device of claim 15, wherein the light redirecting means include a plurality of light redirection features disposed in the light guiding means, each light redirection feature being configured to redirect light incident thereon toward the at least one photovoltaic cell.

17. The device of claim 16, wherein each light redirection feature is aligned with a focal point of one of the plurality of lenses.

18. The device of claim 13, wherein the artificial light providing means includes a plurality of light turning features disposed in the light guiding means, and at least one light source disposed along the second edge of the light guiding means, each light turning feature being configured to turn light received from the at least one light source in a direction away from the light guiding means.

19. A method of manufacturing a device, the method comprising:
providing a first optical structure having a plurality of lenses, each lens being configured to focus light incident on the lens toward a focal point disposed below the plurality of lenses, the first optical structure having a forward surface and a rearward surface;
disposing a second optical structure below the first optical structure, the second optical structure having a forward surface, a rearward surface, a first edge extending between the rearward surface and the forward surface of the second optical structure, and a second edge extending between the rearward surface and the forward surface of the second optical structure;
disposing at least one light source along the first edge of the second optical structure;
forming a plurality of turning features disposed in the second optical structure configured to turn light received from the at least one light source out of the rearward surface of the second optical structure;
disposing at least one photovoltaic cell along the second edge of the second optical structure; and
forming a plurality of light redirection features each disposed in the second optical structure at a focal point of one of the plurality of lenses, the plurality of light redirection features configured to redirect at least a portion of light incident on the forward surface of the first optical structure toward the at least one photovoltaic cell.

20. The method of claim 19, wherein the plurality of lenses include cylindrical-shaped collection lenses aligned in parallel and extending across the forward surface of the first optical structure.

21. The method of claim 20, wherein each light turning feature includes a prismatic feature extending in a direction orthogonal to the alignment of the cylindrical-shaped collection lenses.

22. The method of claim 21, wherein at least some of the light turning features are formed between at least two of the light redirection features.

23. The method of claim 19, wherein the forward surface of the first optical structure includes a first portion and a second portion, wherein the plurality of lenses are disposed over the first portion of the forward surface, and wherein the plurality of lenses are not disposed over the second portion of the forward surface.

24. The method of claim 23, wherein the light turning features are formed below the second portion of the forward surface of the first optical structure.

25. The method of claim 19, further comprising:
providing a battery; and
electrically coupling the at least one photovoltaic cell to the battery.

26. The method of claim 25, further comprising electrically coupling the at least one light source to the battery.

27. The method of claim 19, further comprising electrically coupling the at least one photovoltaic cell to an electrical grid.
